(19) United States
(12) Patent Application Publication
(10) Pub. No.: US 2012/0261652 A1
(43) Pub. Date: Oct. 18, 2012

(54) Electro-Optical, Organic Semiconductor Component and Method for the Production Thereof

(75) Inventors: Carsten Rothe, Dresden (DE); Falk Loeser, Dresden (DE); Rudolf Lessmann, Dresden (DE)

(73) Assignee: NOVALED AG, Dresden (DE)

(21) Appl. No.: 13/501,942

(22) PCT Filed: May 18, 2010
(86) PCT No.: PCT/DE2010/000545

§ 371 Date: Jun. 25, 2012

(30) Foreign Application Priority Data
Oct. 14, 2009 (DE) 10 2009 049 437.5

(51) Int. Cl. H01L 51/52; H01L 51/56

(52) U.S. Cl. 257/40; 438/47; 257/E51.018

(57) ABSTRACT

The invention relates to an electro-optical, organic semiconductor component with a flat arrangement of stacked, organic layers. The invention further relates to a method for producing an electro-optical, organic semiconductor component.

### FIELD OF THE INVENTION

The invention relates to an electro-optical, organic semiconductor component and a production method therefor.

### BACKGROUND OF THE INVENTION

Flat, organic electro-optical components are usually made up of a series of organic layers that are formed between two power-supplying electrodes. The organic layer stack in such components is typically between 50 and 1000 nm thick. Because they are so thin, flat organic components of this kind are prone to short circuits. In this context, the cause of the short circuit is usually a highly localised (typically 100 nm diameter) weakpoint inside the flat component. The increased current flow through the weakpoint causes local heating of the component, which in turn causes the current flow to increase further. The consequence is that ultimately areas of the component surrounding the weakpoint are also degraded. In the end, the entire component suffers a fatal short circuit.

In order to stop this self-acceleration process, it was suggested to introduce current limiting layers or structures into the flat component. Due to their finite resistance, these prevent the current flowing through the weakpoint from rising to practically infinite, and thus also prevent the self-acceleration of the degradation process.

Known current limiting layers are made for example of MoOx, which is applied directly to the anode. However, current limitation may also be achieved via macroscopic structuring of one of the electrodes (see for example US 2008/143250).

In any case, it must be expected that any current limiter will render the component more complex. Moreover, the current limiter must have a resistance of the same magnitude as the local surface resistance of the organic component that is to be protected, since effective protection against local short circuits can obviously only be assured from this serial connection of the two resistors. According to this arrangement, the loss of power due to the additional resistance that is necessarily associated with the current limiting layer has a disadvantageous effect. In other words, according to the prior art components with a current limiting layer are less power efficient than those without a current limiting layer.

### SUMMARY OF THE INVENTION

The object of the invention is to provide an electro-optical, organic semiconductor component and a method for manufacturing such components, with which the configurability of the semiconductor component is made easier both during production and in operation.

This object is solved according to the invention by an electro-optical, organic semiconductor component as recited in independent claim 1 and a method for production thereof as recited in independent claim 12. Advantageous refinements of the invention are the object of the dependent subclaims.

According to one aspect, the invention incorporates the idea of an electro-optical, organic semiconductor component with a flat arrangement of stacked, organic layers and electrical connection contacts that couple the arrangement of stacked organic layers with an electric potential so that the potential may be applied to them, wherein:
the arrangement of stacked organic layers with an organic charge carrier transport layer is formed from one layer material,
the arrangement of stacked organic layers with at least one other organic layer is formed from another layer material that differs from the first layer material,
the electrical conductivity of the organic charge carrier transport layer is thermally irreversibly changeable at least locally by heating the layer material in the arrangement of stacked organic layers at least locally to a temperature that lies between a lower critical temperature Tcmin and an upper critical temperature Tcmax, and
the organic charge carrier transport layer made from the layer material and the at least one other organic layer made from the other layer material are morphologically stable in the temperature range between the lower critical temperature Tcmin and the upper critical temperature Tcmax.

According to another aspect of the invention, a method is provided for producing an electro-optical, organic semiconductor component, wherein the method includes steps for forming a flat arrangement of stacked, organic layers and for forming electrical connection contacts that couple the arrangement of stacked organic layers with an electric potential so that the potential may be applied to them, and wherein
the formation of the arrangement of stacked, organic layers further includes steps for forming an organic charge carrier transport layer from a layer material and for forming at least one other organic layer from another layer material that differs from first layer material,
the electrical conductivity of the organic charge carrier transport layer is thermally irreversibly changeable at least locally by heating the layer material in the arrangement of stacked organic layers at least locally to a temperature that lies between a lower critical temperature Tcmin and an upper critical temperature Tcmax, and
the organic charge carrier transport layer made from the layer material and the at least one other organic layer made from the other layer material are morphologically stable in the temperature range between the lower critical temperature Tcmin and the upper critical temperature Tcmax.

### DESCRIPTION OF THE DRAWINGS

In the following, the invention will be explained in greater detail on the basis of preferred embodiments thereof and with reference to the figures of a drawing. In the drawing:

FIG. 1 is a diagrammatic representation of an organic, electronic component,

FIGS. 2A, 2B, 2C are diagrammatic representations of the formation of a defect, a short-circuit, and prevention thereof,

FIG. 3A is a diagrammatic representation of the deactivation of a dopant,

FIG. 3B is a diagrammatic representation of the deactivation of a transport material,

FIG. 4 A/V characteristic curves,

FIGS. 5A, 5B is a diagrammatic representation of a structuring process using a laser (static, slow variant), and

FIGS. 6A, 6B is a diagrammatic representation of a structuring process using a laser (dynamic, high-speed variant).

### DETAILED DESCRIPTION

With the aid of the invention, it becomes possible to change the distribution of electrical conductivity in an organic charge carrier transport layer of the semiconductor component by applying heat during production or subsequently during operation. This enables the semiconductor component to be configured efficiently for various application purposes.

The organic charge carrier transport layer may be designed as an electron transport layer or a hole transport layer, which means that preferably charge carriers in the form of either electrons or holes are transported by the charge carrier transport layer. In this context, these are charge carriers that are generated when an electrical potential is applied to the arrangement of stacked, organic layers, and are subsequently transported.

The irreversible thermal change in electrical conductivity in the organic charge carrier transport layer may cause an at least locally created increase or reduction in electrical conductivity.

The transport layer is not changed morphologically at a temperature below Tcmax. This means in particular that the layer does not melt and also does not become crystallized, with the result that the layer thickness and its roughness are essentially preserved. Layers that crystallise, for example layers of small molecules, can increase the roughness of the layer to such a degree that the adjacent layers, for example electrodes or other organic layers, come into contact with each other and a short circuit may result. The crystals may also form long needles, which are several times longer than the typical layer thickness and thus puncture the neighbouring layers. It is important to avoid this. Layers that melt are also to be avoided. Their melting usually causes neighbouring layers to be short circuited. Or direct contact with the electrodes Occurs. In this case, it may even happen that neighbouring layers are delaminated.

The electrical conductivity of a layer may be determined by depositing two contacts on a substrate at a distance from one another. The layer is then deposited on this substrate. When a voltage is applied, a current flows through the sensor. Conductivity can then be determined by applying Ohm's law and taking into account the geometry of the sensor.

A preferred refinement of the invention provides that the layer material of the organic charge carrier transport layer contains an organic matrix material and a dopant, with which the matrix material is electrically doped. With the irreversible thermal change in the electrical conductivity of the organic charge carrier transport layer, in this embodiment it may be provided that the electrical doping effect that existed previously is reduced again when the lower critical temperature Tcmin is exceeded, so that the electrical conductivity is diminished at least locally. Doping materials that are used for preference are organic dopants or metalorganic coordination complexes, whose electrical doping effect is based on a partial transfer of the electric charge between the matrix material and the dopant. If the organic charge carrier transport layer is realised as an electron transport layer, the organic layer may be formed from an electron transport material and an n-dopant included therein. If it is a hole transport layer, a hole transport material and a p-dopant will be used.

The electrical conductivity of the doped layer should be greater than the conductivity of the undoped layer at the operating temperature of the component of an electrically doped layer (undoped layers have conductivities of less than 1×10−8 S/cm, usually less than 1×10−10 S/cm), it should particularly be greater than 1×10−6 S/cm, preferably greater than 1×10−5 S/cm, and more preferably greater than 1×10−4 S/cm. With these methods, care should be taken to ensure that the matrix materials are sufficiently pure. Such degrees of purity can be achieved by conventional methods, for example with gradient sublimation.

The dopant (p or n) must be an organic compound or a metalorganic coordination complex. One possible explanation for the change in conductivity of the transport layer is that the doping is deactivated by thermal excitation. Above temperature Tc, a chemical reaction becomes possible that neutralizes the extra charges of the doped organic semiconductor material, most often in an irreversible chemical reaction with the dopant. In certain cases, the products of the chemical reaction can be observed using mass spectroscopy (see S. Scholz, R. Meerheim, B. Lüssem, and K. Leo, Appl. Phys. Lett. 94, 043314 (2009)).

A metalorganic compound that is used as the precursor for metal doping (the metal is the dopant and the organic compound is just a precursor compound), is not a dopant within the meaning of the invention. In the case of metal doping (Li, Cs, and similar), a chemical reaction to deactivate the dopant is not possible. Such doping is also not considered to be organic.

In an expedient variant of the invention, it may be provided that: 85° C.<Tcmin.

An advantageous embodiment of the invention provides that: 120° C.≦Tcmax≦200° C., preferably 140° C.≦Tcmax≦180° C.

A refinement of the invention provides that the layer material and the other layer material have a glass transition temperature Tg for which: Tg≧Tcmax.

In an advantageous variation of the invention, it may be provided that the layer material and the other layer material have a crystallisation temperature Tk for which: Tk≧Tcmax.

A refinement of the invention may provide that the layer material and the other layer material have a sublimation temperature Te for which: Te≧Tcmax.

A preferred refinement of the invention provides that the organic charge carrier transport layer has an electrical conductivity of at least 10-6 S/cm at room temperature.

In an expedient variant of the invention it may be provided that the organic charge carrier transport layer is formed without any direct contact with the electrical connection contacts.

An advantageous embodiment of the invention provides that a short circuit protection layer is formed with the organic charge carrier transport layer. Short circuits in an embodiment may be delayed temporally with the aid of this short circuit protection layer. In addition or alternatively thereto, in one variation electrical short circuits may be prevented entirely with the aid of the short circuit protection layer.

A refinement of the invention preferably provides that the arrangement of stacked organic layers and the electrical connection contacts are configured to provide a component selected from the following group of components: organic electrical resistor and organic light emitting component.

Most recently, a trend has begun towards manufacturing electronic components from organic materials in similar manner to classic semiconductors. These may be electrical components such as transistors or diodes, but they may also be organic light emitting diodes. All of these components should function faultlessly over areas of 100 cm² and more. This presents difficulties because the organic layer stacks are only about 200 nm high. Defects on the substrates used (for example defects in the transparent base electrode (ITO)), in the deposition of the organic layers or the covering electrode, or in other processes can cause significant malfunctions in the layer stack. These malfunctions are often fatal and result in the total failure of the components. Less evident malfunctions may exhibit altered transport properties in the fault area, but to not fail completely until they have been in operation for considerable periods. The reason for this is the faults are often associated with increased local conductivity. This causes local overheating and the destruction of the components inner structure. The reason this causes so much difficulty is precisely because conductivity increases constantly as the temperature rises. This then results in a fatal fault (for example, short circuit, complete destruction of the component structure).

Thus, the transport layer described above prevents the component from failing totally by reducing the component's conductivity above a critical temperature (Tcmin) to such a degree that it is not possible for the site of the fault to continue heating up. However, the critical temperature is below the component's stability temperature. In essence, this effectively prevents the local short circuit from expanding to cause a fatal failure of the entire component. The suggested transport layer forms an integral protection layer in the component.

In one configuration, an OLED has the following layer structure consisting of anode/HTL/organic charge carrier transport layer/EML/ETL/cathode. The ETL is optional, other layers may be used in known manner, such as HIL, EIL, HBL, EBL, and so on. In one configuration, an OLED has the following layer structure consisting of anode/HTL/EML/organic charge carrier transport layer/ETL/cathode. The HTL is optional, other layers may be used in known manner, such as HIL, EIL, HBL, EBL, and so on.

Components are also being manufactured as stacked, organic electro-optical semiconductor components in ever increasing numbers. In this context, two or more electrooptically functional areas—separated by one or more charge carrier transport layers—are placed between a shared electrode pair. The two or more functional units are preferably connected by charge carrier generation layers which are made up of at least one n-doped and one p-doped layer. According to the invention, this charge carrier generation layer may incorporate an organic charge carrier transport layer, which further extends its functional capabilities for a modest cost without limiting its charge carrier generation function.

The simplest charge carrier generation layers comprise at least two layers, for example an n-doped electron transport system and a p-doped hole transport system. Each of these layers may be configured as a charge carrier transport layer with thermally modifiable electrical conductivity.

It is also possible to create charge carrier generation layers from an undoped transport material, an intermediate layer and an oppositely doped charge carrier transport layer, the intermediate layer being purely a dopant that is able to dope the undoped transport material. Even if the transport layer in this case is not doped directly, it will be clear to someone skilled in the art that in this case too it is possible to realise the organic charge carrier transport layer as a combination of an undoped transport layer and the associated pure dopant in physical contact with one another. The doping effect that is important for the functionality of the charge carrier generation layer at the contact layer between the undoped transport layer and the dopant layer is also reduced above the same critical temperature Tcmin at which the conductivity of the directly doped transport layer is also reduced.

It is also possible to create charge carrier generation layers from a pure dopant layer of the charge carrier type, an undoped intermediate layer and an oppositely doped charge carrier transport layer, the pure dopant being able to dope the undoped intermediate layer. Even if the intermediate layer in this case is not doped directly, it will be clear to someone skilled in the art that in this case too it is possible to realise the organic charge carrier transport layer as a combination of an undoped transport layer and the associated pure dopant in physical contact with one another. The doping effect that is important for the functionality of the charge carrier generation layer at the contact layer between the undoped intermediate layer and the dopant layer is also reduced above the same critical temperature Tcmin at which the conductivity of the directly doped transport layer is also reduced.

The embodiments described in the context of the electro-optical organic component may be envisaged correspondingly in conjunction with the method for manufacturing an electro-optical, organic semiconductor component.

A preferred refinement of the method provides that the formation of the arrangement of stacked, organic layers further comprises a step for structuring the organic charge carrier transport layer for the purpose of distributing the electrical conductivity within the organic charge carrier transport layer by heating the organic charge carrier transport layer at least locally to a temperature in the range between the lower critical temperature Tcmin and the upper critical temperature Tcmax.

In a refinement of the production method it may be provided that the formation of the arrangement of stacked, organic layers further comprises a step for homogenising the organic charge carrier transport layer for the purpose of distributing the current density within the organic charge carrier transport layer, by heating the organic charge carrier transport layer at least locally to a temperature in the range between the lower critical temperature Tcmin and the upper critical temperature Tcmax. The current density should be distributed uniformly over the surface. A conductivity gradient towards the surface is created for this purpose.

A common feature of the two process variants described in the preceding is that an electrical conductivity distribution that was originally created when the organic charge carrier transport layer was deposited is at least locally modified afterwards, for purposes of structuring and/or homogenising areas of the organic charge carrier transport layer.

Many different methods may be used to raise the temperature in a least a small area of the component. For example, the temperature may be raised with the aid of a homogeneous thermal flow from electromagnetic radiation sources. Such sources may be conventional lighting devices or laser light sources for example. Preferred sources are electromagnetic radiation sources operating in the near infrared (NIR) wavelength range at wavelengths >650 nm, preferably >800 nm. It is preferable that the temperature is raised by covering the subareas that are not to be irradiated, preferably by arranging one or more shadow masks over the component to reflect the electromagnetic radiation used. One advantage of this method is that the structuring according to the invention may also be carried out through a carrier substrate that is transparent in the wavelength range used, or through an encapsulation, for example a glass substrate or a transparent thin film encapsulation according to the most recent art.

A temperature rise may also be created by structuring the thermal flow of electromagnetic radiation sources. Such sources may be conventional lighting devices or laser light sources for example. Preferred sources are electromagnetic radiation sources operating in the near infrared (NIR) wavelength range. This structuring of the thermal flow is preferably achieved with refractive optical elements. For example, a punctiform local thermal flow may be created by fitting a suitable optical lens. Any other structures may also be created with the aid of such “diffractional optical elements” (DOEs). A high degree of flexibility in structuring (in this case without masks) is achieved at a modest cost if the component and/or the structured thermal flow can be actuated variably in terms of time and/or location. One advantage of this method is that the structuring according to the invention may also be carried out through a carrier substrate that is transparent in the wavelength range used, or through an encapsulation, for example a glass substrate or a transparent thin film encapsulation according to the most recent art.

The temperature rise may also be effected using heat convection. In this case, spatial structuring is effected using for example spatially structured heating plates, which are brought into thermal contact with the component according to the invention. One advantage of this method is that the structuring according to the invention may also be carried out through an opaque material, for example a metal substrate, or through a metal encapsulation.

The methods described in the preceding for creating a local rise in temperature are not exhaustive. Indeed, many other methods, including combinations of different methods, may be used.

An advantageous embodiment provides that if temperature Tcmin is exceeded during the local temperature raising step the conductivity of the organic charge carrier transport layer is reduced irreversibly, so the structures are fixed unchangeably.

According to the invention, a flat, organic, electro-optical semiconductor element that has been produced in accordance with one of the methods of the invention is preferably an organic light emitting diode with a spatial structuring of the light density, which are used as a logo, signboard, decorative application, nameplate, barcode, placard, billboard, light display for display windows or lighting means for living spaces and much more.

If the flat, organic, electro-optical semiconductor element is an OLED, it is also possible according to the invention to adjust the spatial light density in controlled manner and thus compensate in part or completely for the drawbacks of an inhomogeneous light emitting diode for flat OLEDs that are associated with the prior art. In this way, the spatial temperature distribution throughout the component is preferably selected such that the resulting light intensity appears as homogeneous as possible across the entire surface of the component after processing.

The charge carrier transport layers used for homogenising flat light elements are preferably such in which the conductivity is not reduced abruptly, but gradually after Tcmin is reached, at least until the Tcmax temperature is reached. In other words, for such a component there is a continuous dependence on its conductivity at room temperature as a function of the maximum temperature reached locally, S(Tcmax). Since the local conductivity is directly proportional to the local light intensity (luminance), any luminance distribution may thus be created over the surface of the component. The luminance is preferably homogeneous over the entire surface of the component.

If the organic, electro-optical semiconductor component is a component that controls the flow of current flow, for example an organic transistor, any number of individual elements may be produced from a single unstructured component. In combination with a flat lighting element, it is thus possible to create pixelated indicator boards or displays and other such items.

The great attraction of the suggested method consists in that components structured in this way are still extremely efficient. This is illustrated most easily with an equivalent circuit diagram: in principle, the structured component corresponds to a parallel circuit including an efficient, active and an inactive current carrying or partially active element carrying less current, for example a diode. In the forward direction, the inactive or partially active diode has a resistance that is in the order of 2 to 100 times greater than that of the active diode. However, this also means that, according to Kirchoffs laws, only a fraction of the current is drained via the inactive subarea of the OLED. The current density in the active subarea is greater by a factor of from 2 to 100 or more. At the same time, by far the greater part of the incoming electrical energy is also actually used in the areas of the component that emit light, for example. Consequently, the component exhibits high power efficiency.

It was also found that the electrical resistance of the doped semiconductor layers behaves like a normal doped, organic semiconductor until a temperature Tcmin is reached, but that it changes above Tcmin. In the standard doped, organic semiconductor, resistance decreases as the temperature increases. In the semiconductor layers presented here, resistance decreases as the temperature rises, until Tcmin is reached, then resistance increases as the temperature continues to rise until Tcmax is reached. The change in resistance that took place between Tcmin and Tcmax is not reversible upon cooling. This behaviour is used to make a controlled adjustment to the resistance of the layer, or only a part thereof.

Tcmin is defined as the temperature above which the resistance of the doped semiconductor layer changes as the temperature rises, wherein the change in resistance, particularly the increase in resistance, is not reversible.

The OLED may then be structured in a two-stage (binary) structuring process by switching points on the surface to a state of high resistance (switched off). The OLED may then be structured continuous structuring by establishing a stepless resistance gradient.

A refinement of the invention is a light-emitting organic component, particularly a light-emitting organic diode, having an electrode that is spread over an electrode surface and a counter electrode that is spread over a counter electrode surface, and an organic layer arrangement that is formed between the electrode and the counter electrode and is in electrical contact with both, wherein an electrical resistance gradient extending in a direction essentially parallel to the electrode surface is formed in an area of the organic layer arrangement that at least partly overlaps the electrode surface. The resistance gradient is created using the layer invented according to the method described in the preceding. The resistance gradient may also be created by self-heating, by driving the OLED with a very high current density, causing at least part of the surface reaches a temperature equal to or higher than Tcmin.

The electrical resistance gradient may be used to balance out differences in the electrical lead resistance in the electrode surface that usually have a continuous course. The electrical resistance gradient compensates at least in part for the site-dependent electrical lead resistances of the electrode. In this way, the electrical resistance of the light-emitting component is maintained constant to the extent possible over the surface of the component, which results in a constant current flow, so that the light emitted from the component appear uniform and homogeneous. If the electrical resistance gradient is formed over one or more layers of the organic layer arrangement, the electrical resistance changes correspondingly throughout the organic layer arrangement. The change in resistance may be linear or non-liner. Any number of two- or three-dimensional gradient profiles may be produced, and these may comprise constant or inconstant resistance curves as desired, so that a gradient curve is formed in the opposite direction to the curve of the electrical lead resistances, and the variation thereof may be used to compensate in targeted manner completely or partially for the effects thereof over the entire component surface. It is preferred that the layer thickness of the layer with the resistance gradient is constant over the surface of the component. It is also preferred if the doping concentration in the volume of this layer is homogenous.

In the sense understood for the purposes of this document, the term resistanced gradient stands for an electrical resistance that diminishes over a macroscopic sector proceeding away from the starting point in a direction parallel to the surface of the component, as distinct from any local resistance fluctuations that occur on a macroscopic scale in the organic layer arrangement.

FIG. 1 is a diagrammatic representation of an organic, electronic component.

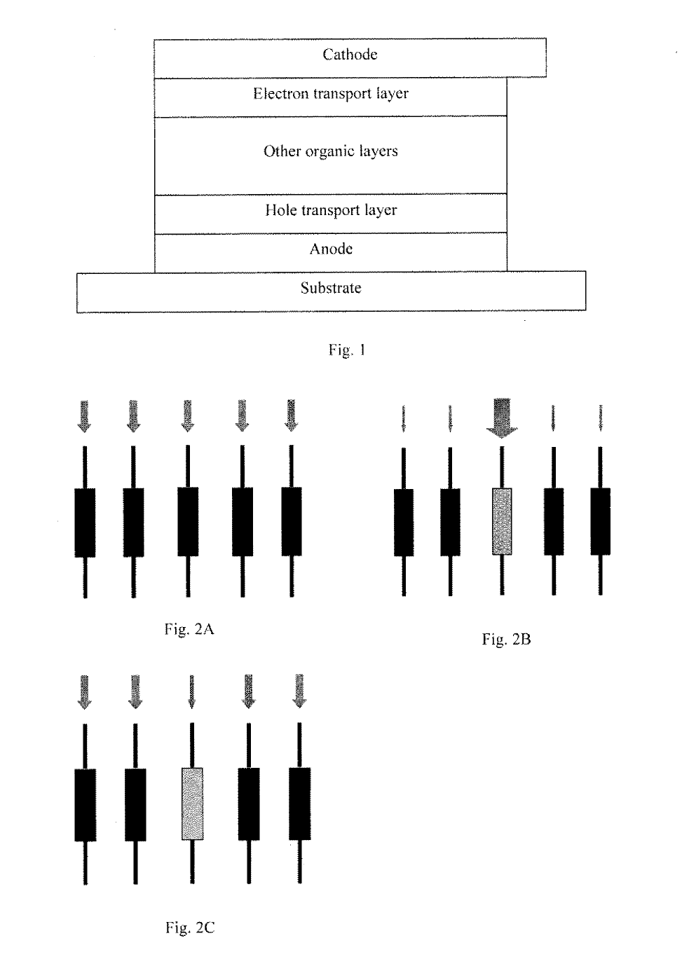

FIGS. 2A, 2B, 2C are diagrammatic representations of the formation of a defect, a short-circuit, and prevention thereof. A flat, organic component may be considered as a parallel circuit of individual components. A local defect in the component surface creates increased conductivity at the defect site, leading to local heating of the surrounding areas of the component as well. If this is not prevented, continued use of the component may ultimately result in its complete destruction (FIG. 2B). The transport layer for which patent protection is sought reduces conductivity above a temperature Tc. It thus prevents both the progressive heating of the fault site, but also the total functional failure of the component (FIG. 2C).

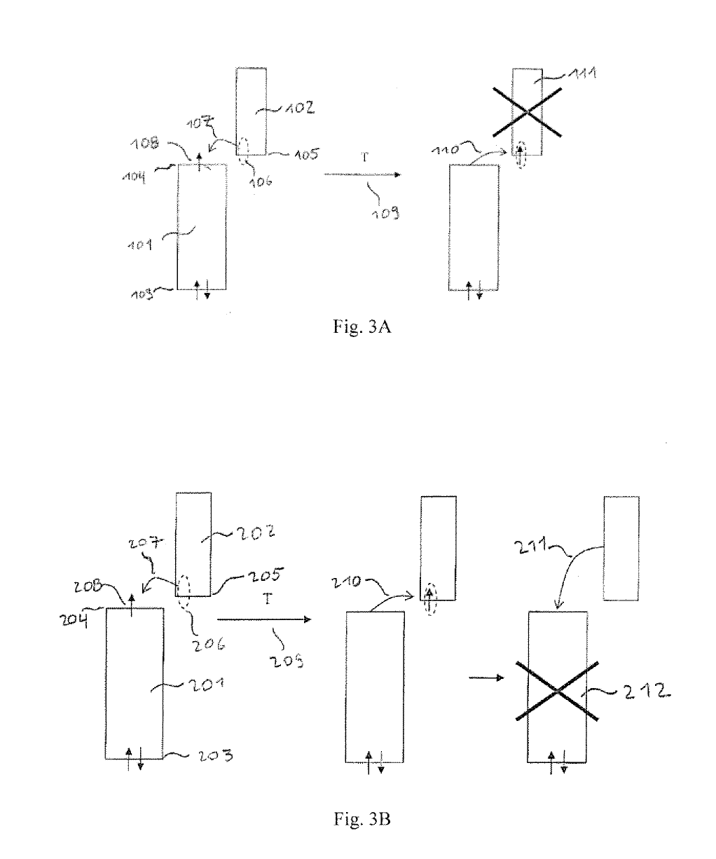

FIGS. 3A and 3B illustrate doping by charge transfer 107 with reference to an ETM 101 and an n-dopant 102. After thermal loading 109, the dopant is deactivated 11 in FIG. 3A. Alternatively, after thermal loading ETM 212 is deactivated by chemical reaction 211 (in FIG. 3B).

The typical structure of an OLED may look like the following:
1. Carrier, substrate, glass for example
2. Electrode, hole injecting (anode=positive terminal), preferably transparent, for example indium tin oxide (ITO)
3. Hole injection layer, for example CuPc (copper phthalocyanine), or starburst-derivatives,
4. Hole transport layer, for example TPD (triphenyl diamine and derivatives thereof),
5. Hole side blocking layer to prevent exciton diffusion from the emission layer and to prevent charge carriers from leaking from the emission layer, for example alpha-NPB (bisnaphthylphenylamino-biphenyl),
6. Light-emitting layer or system of multiple layers contributing to the light emission, for example CBP (carbazole derivatives) with emitter admixture (for example phosphorescenter triplet emitter iridium-tris-phenylpyridine Ir(ppy)₃) or Alq3 (tris-quinolinato-aluminium) mixed with emitter molecules (for example fluorescing singlet emitter qoumarin),
7. Electron-side blocker layer to prevent exciton diffusion from the emission layer and to prevent charge carrier leakage from the emission layer, for example bathocuproine (BCP),
8. Electron transport layer, for example Alq3 (tris-quinolinato-aluminium),
9. Electron injection layer, for example inorganic lithium fluoride (LiF),
10. Electrode, usually a metal with low work function, electron injecting (cathode=negative terminal), for example aluminium.

That is the typical number of possible layers. Of course, some layers may be omitted or a layer (or a material) may fulfil several properties, for example layers 3 and 4, 4 and 5, 3-5 may be combined, and/or layers 7 and 8, 8 and 9, and 7-9 may be combined. Other possibilities provide for mixing the substance from layer 9 into layer 8, and so on.

This structure described the non-inverted (anode on the substrate), substrate-side emitting (bottom-emission) structure of an OLED. There are various concepts to describe OLEDs emitting away from the substrate (see references in DE 102 15 210). A common feature of all is that the substrate-side electrode (the anode in the non-inverted configuration) is then designed as reflective (or transparent for a transparent OLED) and the covering electrode is design (semi-) transparent. This is usually associated with sacrifices in terms of performance parameters.

If the sequence of the layers is inverted (cathode on substrate), these are referred to as inverted OLEDs (see DE 101 35 513). In this case too, performance sacrifices are to be expected unless special measures are implemented.

It is known to alter the electrical properties of semiconductors, particularly their electrical conductivity, by doping, as is also done with inorganic semiconductors such as silicon semiconductors. In this case a change an initially very low conductivity and, depending on the type of dopant used, a change in the semiconductor's Fermi level is achieved by creating charge carriers in the matrix material. In this context, doping causes a rise the conductivity of charge transport layers to increase, thereby reducing Ohmic losses and resulting in improved transfer of the charge carriers between contacts and the organic layer. Doping in the sense of conductivity is characterized by a charge transfer from the dopant to an adjacent matrix molecule (n-doping, electron conductivity increased), and by the transfer of an electron from a matrix molecule to an adjacent dopant (p-doping, hole conductivity increased). The transfer of charges may be incomplete or complete and may be determined for example by interpreting oscillation bands of an FTIR (fourier-transformed infrared-spectroscopy) measurement.

The properties of the various materials involved may be described by the energy positions of the lowest unoccupied molecular orbital (LUMO, synonym: electron affinity) and the highest occupied molecular orbital (HOMO, synonym: ionisation potential).

One method for determining ionisation potentials (IP) is ultraviolet photoelectron spectroscopy (UPS). Ionisation potentials are usually determined or solids, but it is also possible to measure ionisation potentials in the gas phase. The two values differ due to solid body effects, such as the polarisation energy of the holes that are formed in the photoionisation process. A typical value for polarisation energy is about 1 eV, but larger deviations from this may also occur (N. Sato et al., J. Chem. Soc. Faraday Trans 2, 77, 1621 (1981)).

The ionisation potential refers to the start of the photoemission spectrum in the range of the high kinetic energies of the photoelectrons, that is to say the energy of the most weakly bound photoelectrons.

A method related to this, inverted photoelectron spectroscopy (IPES) may be used to determine electron affinities (EA). However, this method is not widely used. Alternatively, solid body energy levels may be determined by electrochemical measurement of oxidation (Eox) or reduction potentials (Ered) in solution. A suitable method is cyclic voltammetry, for example. Empirical methods for deriving the solid body ionisation potential from an electrochemical oxidation potential are known from the literature.

No empirical formulae are known for converting reduction potentials to electron affinities. This is attributable to the difficulty of determining electron affinities. Therefore, a simple rule is often used: IP=4.8 eV+e*Eox (vs. ferrocene/ferrocenium) and EA=4.8 eV+e*Ered (vs. ferrocene/ferrocenium). If other reference electrodes or redox pairs are used for referencing electrochemical potential, conversion methods are known.

It is usual to use the terms “energy of the HOMO” E(HOMO) and “energy of the LUMO” E(LUMO) synonymouly with the terms ionisation energy and electron affinity (Koopmans Theorem). At the same time, it should be borne in mind that the nature of ionisation potentials and electron affinities is such that a higher value means a stronger bond of a liberated or bound electron. The energy scale of the molecular orbitals (HOMO, LUMO) is the opposite of this. Therefore, as a rough approximation: IP=−E(HOMO) and EA=E(LUMO).

The potentials indicated correspond to the solid body potentials.

Hole transport layers (incl. corresponding blockers) usually have HOMOs in the range from −4.5 to −5.5 eV (under vacuum level), LUMOs in the range from −1.5 eV to −3 eV, for emission layer materials the HOMOs are in the range from −5 eV to −6.5 eV, the LUMOs in the range from −2 to −3 eV, for electron transport materials (incl. corresponding blockers) in the range HOMO=−5.5 eV to −6.8 eV, LUMO=−2.3 to −3.3 eV. The work functions of the contact materials are typically in the order of about −4 to −5.3 eV for the anode and −2.7 to −4.5 eV for the cathode.

A dopant for the purposes of the invention is an electrical dopant that increases the density of the charge carriers on a matrix (transport material) by charge transfer and thus also the changes the position of the Fermi level. This dopant and doping are not to be confused with chemical reactions, which change the transport material, or with mixtures between two different carrier materials. A distinction must also be made between doping and emitter doping with dyes.

Document DE 103 07 125 (corresponding to US2005/040390) discloses a doped organic semiconductor material having increased charge carrier density and effective charge carrier mobility, obtainable by doping with a chemical compound, particularly a cationic dye, from which a doping active molecular group is eliminated. Cationic dyes according to the invention may be pyronin B chloride or crystal violet chloride.

Document DE 103 38 406 (corresponding to US 2005/061232) discloses the use of a dopant (particularly of leukobases of cationic dyes), from which certain leaving groups are eliminated in order to obtain a doping effect. A leukobase according to the invention may be leuko-crystal violet for example.

Patent application DE 103 47 856 (corresponding to WO 05/036667) discloses the use of transition metal complexes as donors in an organic semiconductor material. A transition metal complex according to the invention may be Bis(2,2′-terpyridine) ruthenium for example.

Patent application DE 103 57 044 (corresponding to US 2005/121667) discloses the use of quinones or 1,3,2-dioxaborines and derivatives thereof as acceptors in organic semiconductor materials. Acceptors according to the invention are for example 2,2,7,7-Tetrafluoro-2,7-dihydro-1,3,6,8-dioxa-2,7-dibora-pentachloro-benzo[e]pyrene or 1,4,5,8-Tetrahydro-1,4,5,8-tetrathia-2,3,6,7-tetracyanoanthraquinone or 1,3,4,5,7,8-Hexafluoronaphtho-2,6-quinone tetracyanomethane.

Patent application DE 10 2004 010 954 (corresponding to WO 05086251) discloses the use of electron-rich metal complexes as donors in organic semiconductor materials. Electron-rich metal complexes according to the invention are for example Tetrakis(1,3,4,6,7,8-hexahydro-2H-pyrimido[1,2-a]pyrimidinato)dichrome (II) or Tetrakis(1,2,3,3a,4,5,6,6a,7,8-decahydro-1,9,9b-triazaphenalenyl)ditungsten(II) (NDOP-1).

In many cases it is advantageous if for p-doping (n-doping) the LUMO of a p-dopant (HOMO of the n-dopant) is not more than 0.5 eV greater (not more than 0.5 eV less) than the HOMO (LUMO) of a p-type (n-type) matrix. In this context, in keeping with convention, the variables HOMO and LUMO are considered to be quantitatively equivalent to the ionisation potential and the electron affinity respectively, but with opposite signs.

Dopants from the publication EP 2 002 492 (application EP 07 723 337.7) are also preferred.

Donor (n-Dopant)

Molecule and/or neutral radical with a HOMO level (solid body ionisation potential) less (more negative) than −3.3 eV, more preferably less than −2.8 eV and gas phase ionisation potential of −4.3 eV (preferably less than −3.8 eV, more preferably less than −3.6 eV). The HOMO of the donors can be determined from cyclic voltammetric measurements of the oxidation potential. Alternatively, the reduction potential of the donor cation can be determined in a salt of the donor. The donor should have an oxidation potential in respect of Fe/Fc+ (ferrocene/ferrocenium redox pair) that is less than or equal to about −1.5 V, preferably less than or equal to about −2.0 V, more preferably less than or equal to about −2.2 V. The molar mass of the donor is between 200 and 2000 g/mol, preferably between 500 and 2000 g/mol.

Molar doping concentration is between 1:1000 (donor molecule:matrix molecule) and 1:5, preferably between 1:100 and 1:5, more preferably between 1:100 and 1:10. In exceptional cases, a doping ratio in which the doping molecule is used in a concentration higher than 1:5 is conceivable.

It is possible that the donor may be formed as late as during the layer production process or during the subsequent process of producing a layer from a precursor compound (see DE 103 07 125). The HOMO level of the donor indicated in the preceding then refers to the resulting species.

Acceptor (p-Dopant)

Molecule and/or neutral radical with a LUMO level greater (more positive) than −4.5 eV (preferably greater than −4.8 eV, more preferably greater than −5.04 eV). The LUMO of the acceptors can be determined from cyclic voltammetric measurements of the reduction potential. The acceptor should have a reduction potential with respect to Fe/Fc+ that is greater than or equal to about −0.3 V, preferably greater than or equal to about 0.0 V, more preferably greater than or equal to about 0.24 V.

The molar mass of the acceptor is between 200 and 2000 g/mol, preferably between 300 and 2000 g/mol, more preferably between 400 g/mol and 2000 g/mol.

Molar doping concentration is between 1:1000 (acceptor molecule:matrix molecule) and 1:5, preferably between 1:100 and 1:5, more preferably between 1:100 and 1:10. In exceptional cases, a doping ratio in which the doping molecule is used in a concentration higher than 1:5 is conceivable.

It is possible that the acceptor may be formed as late as during the layer production process or during the subsequent process of producing a layer from a precursor compound. The LUMO level of the acceptor indicated in the preceding then refers to the resulting species.

### HTM

Matrix materials for hole transport layers (HTM) are usually neutral, non-radically conjugated molecules. By doping with acceptor compounds, correspondingly singly charged (rarely multiply charged) cations are formed from the matrix material. If a singly charged cation is formed, it is a radical cation. The layer formed from the matrix material and the dopant thus contains neutral molecules of the matrix material and cations of the matrix material formed by doping.

In general, doping causes the charge state of the matrix molecule to be shifted by one or more positive charges. For example, if the matrix material is itself an anion, doping will transform the anion into a neutral molecule or a cation.

Hole transport materials for organic components usually have an oxidation potential in the range from 0V vs. Fc/Fc+ to 0.9 V vs. Fc/Fc+, wherein a range between 0.1 V vs. Fc/Fc+ to 0.4V vs. Fc/Fc+ is considered to be particularly favourable for OLED applications.

A further requirement for a matrix material for hole transport layers is that is should have finite mobility for holes. In this context, hole mobility of >1×10-8 cm2/Vs, preferably >1×10-6 cm2/Vs is advantageous.

Particularly when components are to be produced with solvent processes, polymer matrix materials may also be considered. These are subject to similar requirements in terms of mobility and oxidation potential. Polythiophenes or derivatives thereof for example may serve as a suitable matrix material.

Known HTMs with a high Tg are for example:

| Name | Tg |
|---|---|
| 4,4′,4″-tri(N-dibenzo[a,g]carbazolyl)triphenylamine | 212° C. |
| DiNPB N,N′-Diphenyl-N,N′-bis(4′-(N,N-bis(naphtha- | 157° C. |
| 1-yl-amino)-biphenyl-4-yl)-benzidine | |
| CuPc or ZnPc | 240° C. |

### ETM

Matrix materials for electron transport layers (ETM) might be produced from substances such as fullerenes, for example C60, oxadiazole derivatives, such as 2-(4-Biphenyl)-5-(4-tert-butylphenyl)-1,3,4-oxadiazole, quinoxaline-based compounds such as Bis(phenylquinoxaline), or oligothiophenes, perylene derivatives, such as perylenetetracarboxylic acid anhydride, naphthalene derivatives, such as naphthalenetetracarboxylic acid anhydride, or other electron transport materials.

Materials such as C60 and NTCDA are not used for certain applications, for example C60 is not used as a transport layer in OLEDs with a blue emission fraction (for example white or blue-green), because C60 is too strongly absorbent, and at the same time the LUMO of C60 is too low. NTCDA is crystallised transparently but below 85° C.

Quinolinato complexes, of aluminium or other primary group metals for example, may also be used as matrix materials for electron transport layers, in which case the quinolinato ligand may also be substituted. In particular, the matrix material may be Tris(8-hydroxyquinolinato)-aluminium. Other aluminium complexes with O— and/or N— donor atoms may be used if desired. The quinolinato complexes may contain for example one, two or three quinolinato ligands, wherein the other ligands preferably form complexes with O— and/or n-donor atoms on the central atom, like the Al complex referred to in the following.

Matrix materials for electron transport layers are usually neutral, non-radical conjugated molecules. By doping with donor compounds, correspondingly singly charged (rarely multiply charged) anions are formed from the matrix material. If a singly charged anion is formed, it is a radical anion. The layer formed from the matrix material and the dopant thus contains neutral molecules of the matrix material and anions of the matrix material formed by doping.

In general, doping causes the charge state of the matrix molecule to be shifted by one or more negative charges. For example, if the matrix material is itself a cation, doping will transform the cation into a neutral molecule or an anion.

Matrix materials for electron transport layers in organic light emitting diodes often have a reduction potential between −1.9V vs. Fc/Fc+ and −2.4V vs. Fc/Fc+.

A further requirement for a matrix material for electron transport layers is that is should have finite mobility for electrons. In this context, electron mobility of >1×10-8 cm2/Vs, preferably >1×10-6 cm2/Vs is advantageous.

Particularly when components are to be produced with solvent processes, polymer matrix materials may also be considered. These are subject to similar requirements in terms of mobility and oxidation potential. Polyfluorenes or derivatives thereof for example may serve as a suitable matrix material.

In addition heteroaromatics such as triazole derivatives in particular may be used as matrix materials, possibly also pyrroles, imidazoles, triazoles, pyridines, pyrimidines, pyridazines quinoxalines, pyrazino-quinoxalines and similar. The heteroaromatics are preferably substituted, particularly aryl-substituted, for example phenyl- or naphthyl-substituted. The triazole described below may particularly be used as a matrix material.

ETMs with a high Tg are for example:

| Name | Tg |
|---|---|
| Diazapyrene | >200° C. |
| Metal quinoxaline | >200° C. |
| CuPc or ZnPc | 240° C. |

### Transport Material for the Organic Charge Carrier Transport Layer (HTM and ETM)

The organic charge carrier transport layer contains a transport material as its primary substance. Besides the properties described in the sections “HTM” or “ETM”, the carrier material must also be transparent in the visible range, have a HOMO-LUMO separation of at least 2.7 eV, preferably >3 eV, and mobility greater than 1×10-4 cm2/Vs.

Preferred transport materials for the organic charge transport layer are metal-organic coordination complexes. Other preferred transport materials for the organic charge transport layer are metal-organic coordination complexes in which the ligands are not directly chemically bonded with each other, such as for example metal quinolines and metal quinoxalines (compounds such as CuPc and ZnPc are excluded from these).

Preferred ETMs are quinoxaline compounds having formula:

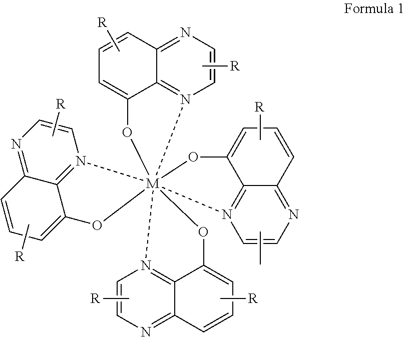

wherein M is selected from Ti, Zr, Hf, Nb, Re, Sn and Ge, each R is selected independently from the group of hydrogen, C1-C20-alkyl, C1-C20-alkenyl, C1-C20-alkinyl, aryl, heteroaryl, oligoaryl, oligoheteroaryl, oligoarylheteroaryl, —ORx, —NRxRy, —SRx, —NO2, —CHO, —COORx, —F, —Cl, —Br, —I, —CN, —NC, —SCN, —OCN, —SORx, SO2Rx, wherein Rx and Ry are selected from C1-C20-alkyl, C1-C20-alkenyl and C1-C20-alkinyl, or one or more R in each ligand may be part of a condensed ring system.

Quinoxaline compound according to formula I, wherein R is selected from the group of aryl, heteroaryl, oligoaryl, oligoheteroaryl and oligoarylheteroaryl, wherein all obei sämtliche sp2-hybridised carbon atoms that do not serve to link a ring may independently of each other be substituted with H, C1-C20-alkyl, C1-C20-alkenyl, C1-C20-alkinyl, —ORx, —NRxRy, —SRx, —NO2, —CHO, —COORx, —F, —Cl, —Br, —I, —CN, —NC, —SCN, —OCN, —SORx, —SO2Rx, wherein Rx and Ry are defined as in claim 1.

Preferred examples are: tetrakis(2,3-dimethylquinoxaline-5-yloxy)zirconium (ETL3);

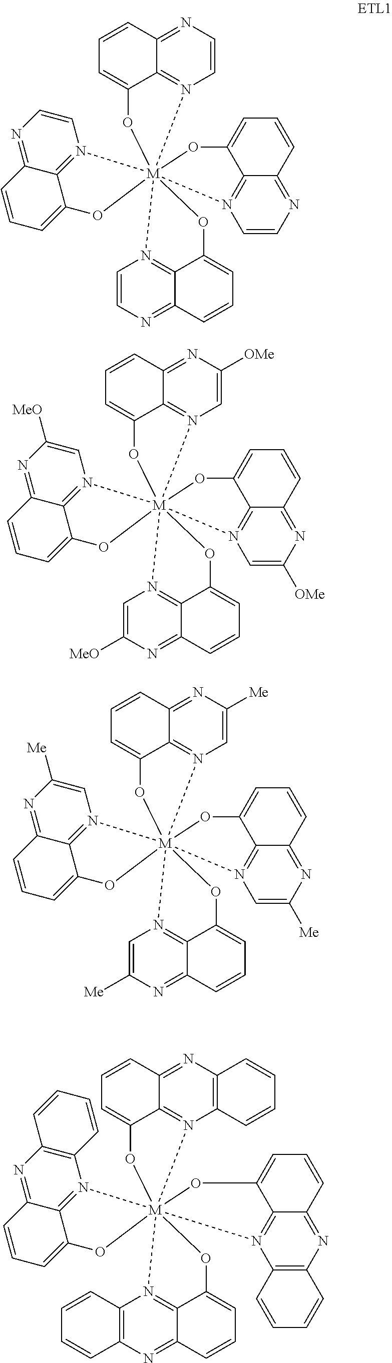

Using an organic charge carrier transport layer as described above in organic light emitting diodes, it has been demonstrated that the mechanism described in the preceding is successful and effective. The structure shown in FIG. 1 was used to produce OLEDs having a size of 4 cm², wherein the organic charge carrier transport layer was used as the ETL. OLEDs with the same geometry and the same other OLED properties are produced to serve as a reference. In this case, only one other electron transport layer not according to the invention was used. 18 OLEDs of each type were examined. Besides the initial yield analysis, another object of the comparison was a long-term operation of the OLEDs.

There were no initial total failures among the OLEDs. Subsequently, the OLEDs were operated for 72 hours with a current density of 12 mA/cm² (˜1000 cd/m²). In this test, the OLEDs without the transport layer according to the invention failed. Then, the operating current was increased to 48 mA/cm² (˜4000 cd/m). At this stage, 2 more reference components failed within 72 hours. None of the components equipped with the transport layer failed during the operating phase, which lasted a total of 200 h.

Whereas none of the components failed totally in the OLEDs that contain the transport layer, 8% of the reference OLEDs without the organic charge carrier transport layer failed in the first 140 h.

### Example 2

### OLED

The OLED was produced with the following layer structure:

ITO anode/p-doped EL301 (5 nm) as HIL/EL301 (from Hodogaya Chemical Co.) as HTL/EL301 as EBL/TMM004 (from Merck & Co.)):ADS068RE (from American Dye Source, Inc) as EML/TMM004 as HBL/ETL-2 as organic charge carrier transport layer/cathode.

### Example 3

### OLED

The OLED was produced with the following layer structure:

ITO anode/p-doped EL301 (5 nm) as HIL/EL301 (from Hodogaya Chemical Co.) as HTL/EL301 as EBL/TMM004 (from Merck & Co.)):ADS068RE (from American Dye Source, Inc) as EML/TMM004 as HBL/ETL-2 as organic charge carrier transport layer doped with NDOP-1 (3 mol %, 15 nm)/ETL-3 doped with NDOP-1 (3 mol %, 40 nm) as ETL/cathode.

### Example 4

### OLED

The OLED was produced with the following layer structure:

ITO anode/p:doped EL301 (5 nm) as HIL/EL301 (from Hodogaya Chemical Co.) as HTL/EL301 as EBL/TMM004 (from Merck & Co.)):ADS068RE (from American Dye Source, Inc) as EML/TMM004 as HBL/ETL-2 as organic charge carrier transport layer doped with NDOP-1 (3 mol %, 15 nm)/ETL-3 as ETL doped with NDOP-1 (3 mol %, 40 nm)/cathode.

### Example 5

### Changing the Electrical Conductivity

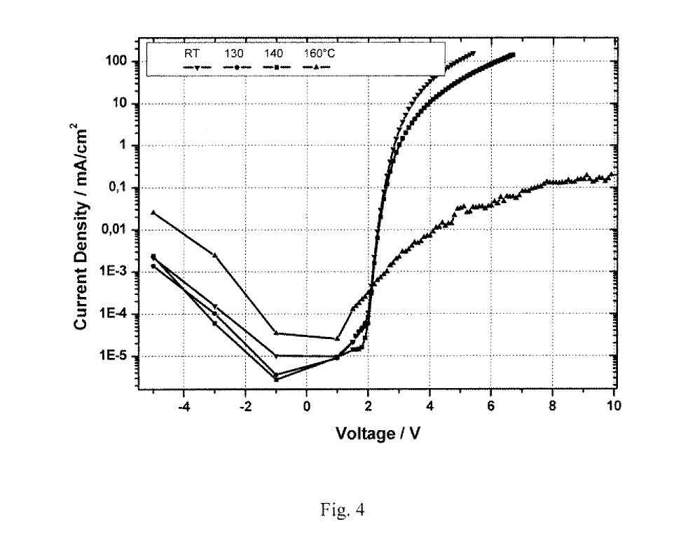

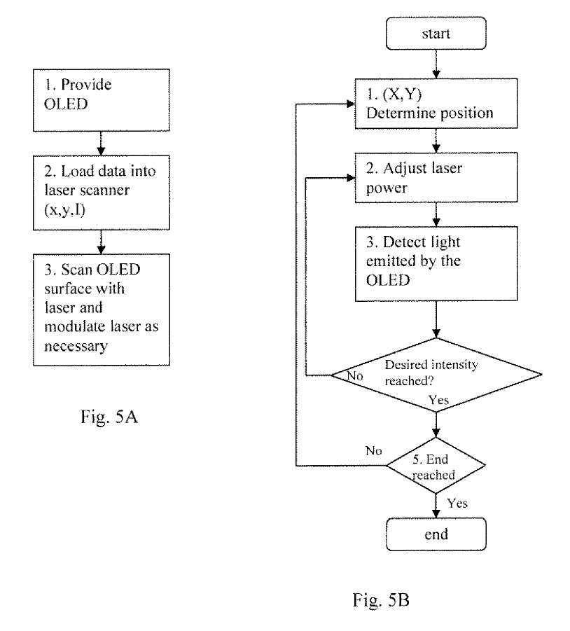

An organic charge carrier transport layer was fitted in an OLED as an electron transport layer. For comparison purposes, OLEDs were produced with another, non-organic charge carrier transport layer. Both OLED types were systematically heated as a whole and a current-voltage characteristic curve was measured after each heating step. It was revealed that the conductivity fails significantly and continuously between 130 and 160° C. Te is thus greater than or equal to 140° C. However, Tc is well below that stability temperature of the OLED, since it still functions as an organic light emitting diode, though now with higher operating voltages, but no short circuits occur. (see FIG. 4)

FIG. 5A shows the process steps for structuring with a laser. In this variant an OLED is provided. The process data (layout data) is loaded into the controller. Then, the surface of the OLED is scanned by the laser. FIG. 5B shows a variation on the method of FIG. 5A, in this case the light of the OLED is detected after the laser treatment, if the desired intensity has not yet been reached (intensity reduction) the laser treatment is repeated.

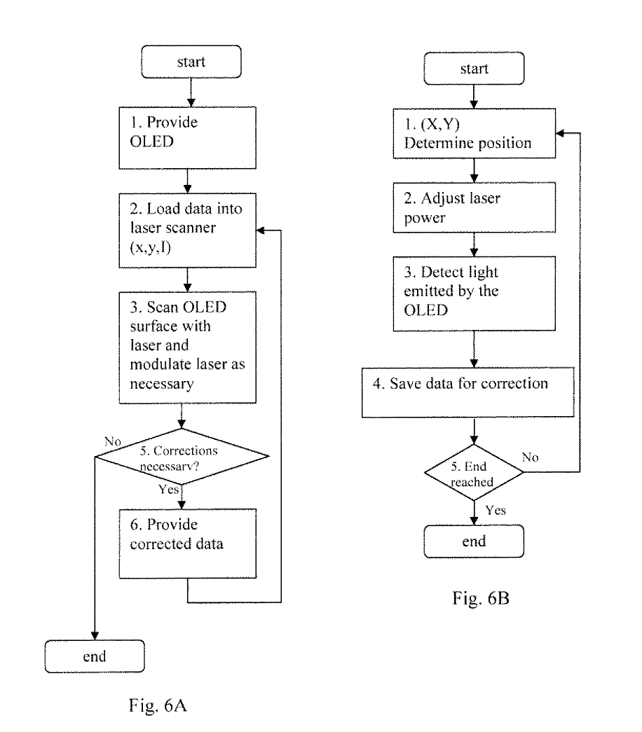

FIG. 6A shows a dynamic method for structuring with a laser. This method has the advantage that it can be implemented at high speed. The OLED is provided, the data is loaded into the computer, the surface of the OLED is scanned, in this case the laser beam is directed continuously over the OLED surface (at constant speed, for example). The position of the laser beam on the surface is calculated and determined, and the laser intensity is adjusted (modulated) so that the desired pattern is engraved in it. After the entire surface has been scanned, it can be decided whether corrections are necessary, and any corrections are made as necessary.

In the variant in FIG. 6B, the method is carried out on an OLED that is in operation, and the intensity of the OLED is also measured during scanning. Data for possible correction is calculated and stored. Correction can be carried out if necessary.

The features of the invention disclosed in the preceding description, and also in the claims and the drawing, may be significant both individually and in any combination for the implementation of the invention in its various embodiments.

List of Abbreviations Used

OLED—organic light emitting diode
TM—organic semiconductor material
OHLS—organic semiconductor layer
HTM—organic hole transport material
ETM—organic electron transport material
TL—organic transport layer
HTL—organic hole transport layer
ETL—organic electron transport layer
p:HTL—p-doped organic hole transport layer
n:ETL—n-doped organic electron transport layer
HOMO—highest occupied molecule orbital (synonym: ionisation potential)
LUMO—lowest unoccupied molecule orbital (synonym: (−1)electron affinity)
SPL—short-circuit protection layer
Tc—critical temperature (Tcmin, Tcmax)
Tg—glass transition temperature
TDD—thermally deactivatable doping
RT—room temperature (293 K)
HIL—hole injection layer
EIL—electron injection layer
HBL—hole blocking layer.
EBL—electron blocking layer.

1. An electro-optical, organic semiconductor component comprising, a flat extending arrangement of stacked organic layers, and one or more electrical connection contacts, wherein the one or more electrical connection contacts couple the arrangement of stacked organic layers with an electric potential so that the electric potential may be applied to the arrangement of stacked organic layers, wherein:
the arrangement of stacked organic layers comprises an organic charge carrier transport layer comprising a first layer material,
the arrangement of stacked organic layers comprises at least one organic layer other than the organic charge carrier transport layer, wherein the at least one organic layer other than the organic charge carrier transport layer comprises a second layer material that differs from the first layer material,
the electrical conductivity of the organic charge carrier transport layer is thermally irreversibly changeable at least locally by heating the first layer material in the arrangement of stacked organic layers at least locally to a temperature that lies between a lower critical temperature Tcmin and an upper critical temperature Tcmax, and
the organic charge carrier transport layer and the at least one other organic layer other than the organic charge carrier transport layer are morphologically stable in the temperature range between the lower critical temperature Tcmin and the upper critical temperature Tcmax.

2. The semiconductor component as recited in claim 1, wherein the first layer material comprises an organic matrix material and a doping material, wherein the matrix material is doped with the doping material.

3. The semiconductor component as recited in claim 1, wherein 85° C.<Tcmin.

4. The semiconductor component as recited in claim 1, wherein 120° C.≦Tcmax≦200° C.

5. The semiconductor component as recited in claim 1, wherein the first layer material and the second layer material have a glass transition temperature Tg, for which: Tg≧Tcmax.

6. The semiconductor component as recited in claim 1, wherein the first layer material and the second layer material have a crystallisation temperature Tk for which: Tk≧Tcmax.

7. The semiconductor component as recited in claim 1, wherein the first layer material and the second layer material have a sublimation temperature Te, for which: Te≧Tcmax.

8. The semiconductor component as recited in claim 1, wherein the organic charge carrier transport layer has an electrical conductivity of at least 10⁻⁶ S/cm at room temperature.

9. The semiconductor component as recited in claim 1, wherein the organic charge carrier transport layer lacks direct physical contact with the electrical connection contacts.

10. The semiconductor component as recited in claim 1, wherein the organic charge carrier transport layer comprises a short-circuit protection layer.

11. The semiconductor component as recited in claim 1, wherein the arrangement of stacked organic layers and the one or more electrical connection contacts are configured as a component selected from the following group of components consisting of: organic electrical resistor and organic light-emitting diode.

12. A method for producing an electro-optical organic semiconductor component, wherein the method comprises:
forming a flat arrangement of stacked organic layers; and
forming one or more electrical connection contacts that couple the arrangement of stacked organic layers with an electric potential so that the potential may be applied to the arrangement of stacked organic layers, and wherein
the step of forming the arrangement of stacked organic layers comprises forming an organic charge carrier transport layer from a first layer material and forming at least one organic layer other than the organic charge carrier transport layer from a second layer material that differs from first layer material,
the electrical conductivity of the organic charge carrier transport layer is thermally irreversibly changeable at least locally by heating the first layer material in the arrangement of stacked organic layers at least locally to a temperature that lies between a lower critical temperature Tcmin and an upper critical temperature Tcmax, and
the organic charge carrier transport layer made from the first layer material and the at least one organic layer other than the organic charge carrier transport layer made from the second layer material are morphologically stable in the temperature range between the lower critical temperature Tcmin and the upper critical temperature Tcmax.

13. The method as recited in claim 12, wherein the step of forming the arrangement of stacked organic layers further comprises structuring the organic charge carrier transport layer for the purpose of distributing the electrical conductivity within the organic charge carrier transport layer by heating the organic charge carrier transport layer at least locally to a temperature in the range between the lower critical temperature Tcmin and the upper critical temperature Tcmax.

14. The method as recited in claim 12, wherein the step of forming the arrangement of stacked organic layers further comprises homogenising the organic charge carrier transport layer for the purpose of distributing the current density within the organic charge carrier transport layer, by heating the organic charge carrier transport layer at least locally to a temperature in the range between the lower critical temperature Tcmin and the upper critical temperature.

15. The semiconductor component as recited in claim 4, wherein 140° C.≦Tcmax≦180° C.
